(19) United States
(12) Patent Application Publication
(10) Pub. No.: US 2009/0167395 A1
(43) Pub. Date: Jul. 2, 2009

(54) HIGH PERFORMANCE LATCHES

(75) Inventor: Patrick Bosshart, Plano, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/967,852

(22) Filed: Dec. 31, 2007

(51) Int. Cl. H03K 3/356; H03K 3/00

(52) U.S. Cl. 327/208; 327/199; 327/217

(57) ABSTRACT

An integrated circuit includes at least one latch circuit (300). The latch circuit (300) includes a first stage comprising a latch node (311) positioned between a first pull up device (303) operable to receive a first data signal and a first pull down device (302) operative to receive second data signal. A second stage includes a second pull up device (323) and a second pull down device (322) having the latch node (311) therebetween, wherein at least one gate of the first pull up or first pull down device (302, 303) is directly coupled to a gate of the second pull up or second pull down device (322, 323). An output inverter (330) is coupled to the latch node (311).

### TECHNICAL FIELD OF THE INVENTION

The present invention relates generally to latch circuits.

### BACKGROUND OF THE INVENTION

When designing circuitry using dynamic logic such as domino logic, it is often the case that signals produced by these domino gates are dual-rail, with one clocked output signal representing a data 1 and the other clocked signal representing a data 0. These signals are in an appropriate form to apply as inputs to a subsequent dynamic gate, such as a domino logic gate. In these systems, some of the slower circuitry may be implemented in static logic in order to reduce the power dissipation. However, dual rail clocked signals are not in a form that the static logic portion of the circuitry can generally use. In order to be useful for static gates, it is customary that the input signals be latched.

FIG. 1 shows typical clocked signal and latched signal waveforms. Whereas clocked signals rise on the rising edge of a clock signal clk after some delay and fall on its falling edge with some delay, the latched signals transition in either direction only on the rising edge of clk (after some time delay) as shown.

FIG. 2A shows a conventional latch circuit 200 which accomplishes the latching function responsive to positive logic levels (high active). The inputs of circuit 200 are the two dual rail clocked signals (D, Dx) and its outputs are complementary static latched signals (L, Lx). Latch circuit 200 is shown including a simple NOR latch 202 comprising cross-coupled NOR gates 203 and 204 which implement an RS latch. Latch circuit 200 also includes inverters 206 and 207 on the respective outputs. It is expected that the D and DX inputs are not both high at the same time.

FIG. 2B shows a schematic of a conventional NOR2 gate 250 that is generally used to implement NOR gates 203 and 204 and thus NOR latch by cross coupling two NOR2 gates. NOR2 gate 250 includes series connected PMOS transistors 251 and 252 between Vdd and its output node (OUT) and two parallel connected NMOS transistors 261 and 262 between the output node and ground.

Circuit 200 shown in FIG. 2A has several features which result in relatively poor delay performance (high latency). A rising input on the D input creates a falling transition at the NOR gate 203 output NX, and a rising transition at the output L. NX falling also then causes N to rise and LX to fall. So while there are two (2) inversion delays from D rising to L rising, there are three (3) inversion delays from D rising to LX falling. Referring now to FIG. 2B, one of those inversions is through the two series P-channel transistors 251 and 252) of the bottom NOR2 gate. Note that after D rises and potentially causes the latch circuit 200 to change state, D is expected to return to a low value before DX could rise to flip the latch circuit 200 to the opposite state. What is needed is a new latch design that provides less latency.

### SUMMARY

This Summary is provided to comply with 37 C.F.R. §1.73, requiring a summary of the invention briefly indicating the nature and substance of the invention. It is submitted with the understanding that it will not be used to interpret or limit the scope or meaning of the claims.

An integrated circuit includes at least one latch circuit. The latch circuit includes a first stage comprising a latch node positioned between a first pull up device operable to receive a first data signal and a first pull down device operative to receive second data signal. A second stage includes a second pull up device and a second pull down device having the latch node therebetween, wherein at least one gate of the first pull up or first pull down device is directly coupled to a gate of the second pull up or second pull down device. An output inverter is coupled to the latch node, and in one embodiment provides an output for the latch circuit. As defined herein, “directly coupled” refers to a low resistance connection without any intervening devices, such as diodes or transistors.

### BRIEF DESCRIPTION OF THE DRAWINGS

FIG. 1 shows conventional clocked signal and latched signal waveforms.

FIG. 2A shows a known RS latch arrangement based on cross coupled NOR2 gates, while FIG. 2B shows a schematic of a conventional NOR2 gate implementation.

FIG. 3 shows an RS latch according to an embodiment of the invention.

FIG. 4 shows a circuit arrangement comprising an RS latch according to an embodiment of the invention which is a complementary output version of the RS latch shown in FIG. 3.

FIG. 5A shows a conventional cross-coupled NAND latch arrangement, while FIG. 5B shows a schematic of a conventional NAND gate implementation.

FIG. 6 shows an RS latch according to an embodiment of the invention, having negative logic inputs.

FIG. 7 shows a low active complementary output RS latch according to an embodiment of the invention.

FIG. 8 shows a domino gate with latched output according to an embodiment of the invention.

FIG. 9 is an exemplary layout of an RS latch, according to an embodiment of the invention.

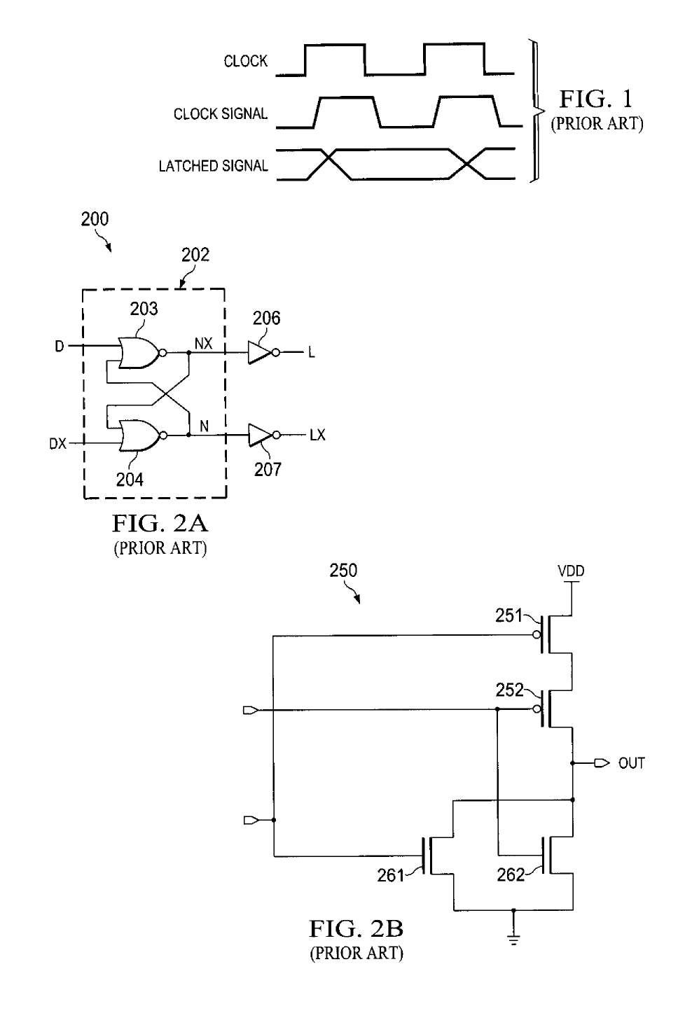

### DETAILED DESCRIPTION

The present invention is described with reference to the attached figures, wherein like reference numerals are used throughout the figures to designate similar or equivalent elements. The figures are not drawn to scale and they are provided merely to illustrate the instant invention. Several aspects of the invention are described below with reference to example applications for illustration. It should be understood that numerous specific details, relationships, and methods are set forth to provide a full understanding of the invention. One having ordinary skill in the relevant art, however, will readily recognize that the invention can be practiced without one or more of the specific details or with other methods. In other instances, well-known structures or operations are not shown in detail to avoid obscuring the invention.

Embodiments of the invention include an integrated circuit comprising at least one latch circuit. The latch circuit comprises a first stage comprising a latch node positioned between a first pull up device operable to receive a first data signal and a first pull down device operative to receive second data signal. A second stage comprises a second pull up device and a second pull down device having the latch node therebetween, wherein at least one gate of the first pull up or first pull down device is directly coupled to a gate of the second pull up or second pull down device. An output inverter is coupled to the latch node. Hold circuitry is generally coupled between an output of said latch circuit and the latch node and is operative to hold the output of the clocked latch circuit.

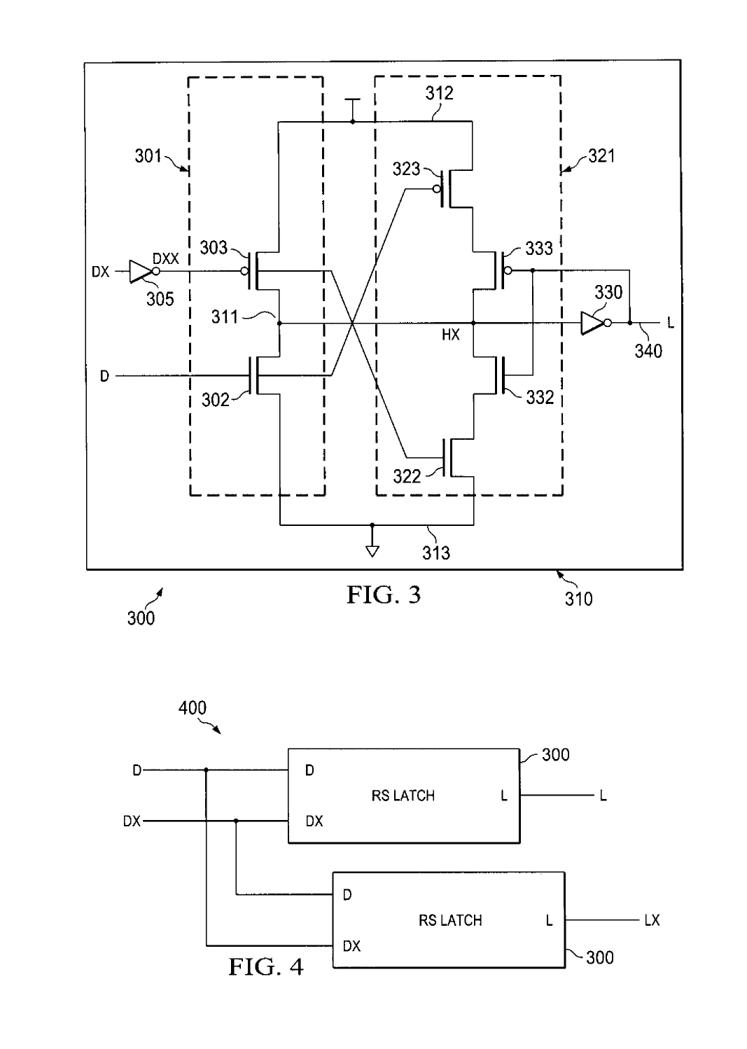

FIG. 3 shows an exemplary integrated circuit 310 comprising an RS latch 300 according to an embodiment of the invention. RS latch comprises a first stage 301 comprising a first NMOS pull down transistor 302 operative to receive a first data signal shown as D and a first PMOS pull up transistor 303 operative to receive a second data signal shown as Dxx, wherein a latch node 311 (shown as HX) is positioned between transistors 302 and 303. An input inverter 305 inverts Dx to provide Dxx. A second stage 321 comprises a second NMOS pull down transistor 322 and a second PMOS pull up transistor 323 having the latch node 311 positioned. A gate of the first PMOS transistor 303 is shown coupled to a gate of the second NMOS transistor 322 and a gate of the first NMOS transistor 302 is shown coupled to a gate of the second PMOS transistor 323. An output inverter 330 is coupled to the latch node 311, an output of the output inverter 340 shown as L is generally the output provided by latch circuit 300.

Transistors shown as 332 and 333 form part of a gated inverter feedback circuit, holding the voltage value at the latch (storage) node 311 when both inputs D and DX are low, a condition that would otherwise leave the latch node 311 floating. Transistor 322 allows transistor 332 to hold the latch node 311 low, only when the DX input is not trying to pull latch node 311 high. Likewise, transistor 323 allows transistor 333 to hold the latch node 311 high only when the D input is not trying to pull the latch node 311 low.

In operation of latch circuit 300, a rising edge on the D input causes the latch node 311 to fall, creating a rising edge on the output L. A rising edge on DX causes DXX to fall, the latch node 311 to rise, and L to fall. As with RS latch 200 shown in FIG. 2A, it is expected that D and DX are never simultaneously high. Like the RS latch 200 shown in FIG. 2A, RS latch 300 has two inversions from a rising D input to a rising output, and three inversions from a rising DX input to a falling output.

However, in the case of RS latch 300, all of the signal paths have only one transistor in series from the positive supply or negative supply (e.g. ground) to the output node of that inversion, whereas in the conventional NOR latch shown in FIG. 2A, two of those inversions are through NOR gates. Discounting the relatively small feedback transistors 333 and 332 as described above that hold the state of latch node 311 in a capacitance analysis, there is only one NMOS device and one PMOS device driving the latch node 311, whereas the conventional NOR gate 250 shown in FIG. 2B has two parallel connected NMOS devices on the output node, resulting in significantly increased capacitance.

In one embodiment, the inverter 305 coupled to receive the DX input could be skewed by making its NMOS transistor W/L ratio larger relative to its standard ratio to its PMOS transistor, to reduce its delay time from the rising edge of DX. A standard ratio of PMOS to NMOS which is generally reflected throughout the circuit for inverters other some other complementary circuits having generally balanced PMOS and NMOS, is generally about 1.4. As used herein, a “larger” transistor in an inverter refers to a W/L ratio of the larger transistor being at least 10%, such as at least 25% greater than the W/L ratio using the standard ratio. For example, if the standard ratio is 1.4 (NMOS about 71% of the size of the PMOS), a 10% larger NMOS would be about 78% the size of the corresponding PMOS. Since the falling edge of DX does not influence flipping for latch 300, skewing the inverter 305 to increase the delay of its rising edge does not generally slow circuit operation.

FIG. 4 shows an RS latch 400 according to an embodiment of the invention which is a complementary output version of the RS latch 300 shown in FIG. 3. RS latch 400 comprises two RS latches 300 connected with swapped inputs D and DX. This circuit arrangement may be used when complementary output signals with minimum latency are both desired. Alternatively, an additional output inverter can be added to the L output 340 of RS latch 300 to provide the complementary output at the cost of the delay of that additional inversion. However, RS latch 400 as shown in FIG. 4 avoids such a delay.

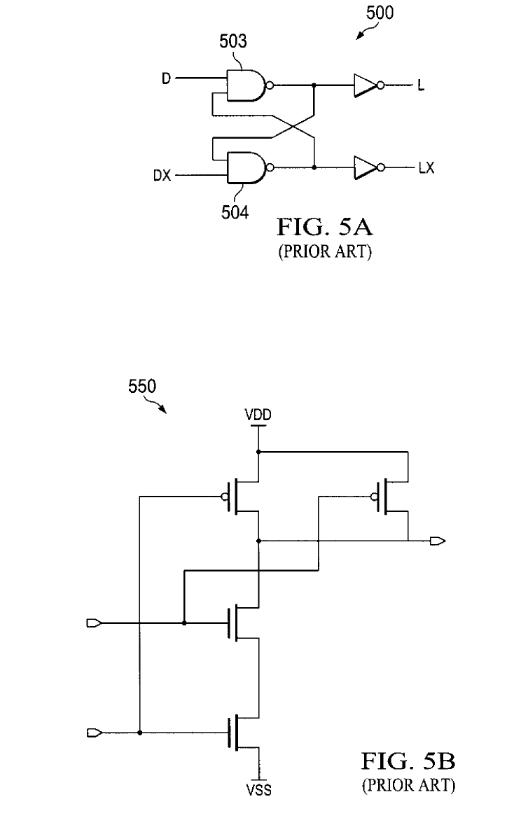

FIG. 5A shows a prior art cross-coupled NAND based RS latch 500 comprising cross coupled NAND gates 503 and 504. NAND-based latch 500 responds to negative logic levels at its inputs rather than the positive logic levels used by NOR-based latch 200 shown in FIG. 2A, and generally offers better delay characteristics than its NOR counterpart because of the improved delay characteristics of NAND gates as compared to NOR gates. FIG. 5B shows a schematic of a conventional NAND2 gate 550 that is generally used to implement NAND gates 503 and 504.

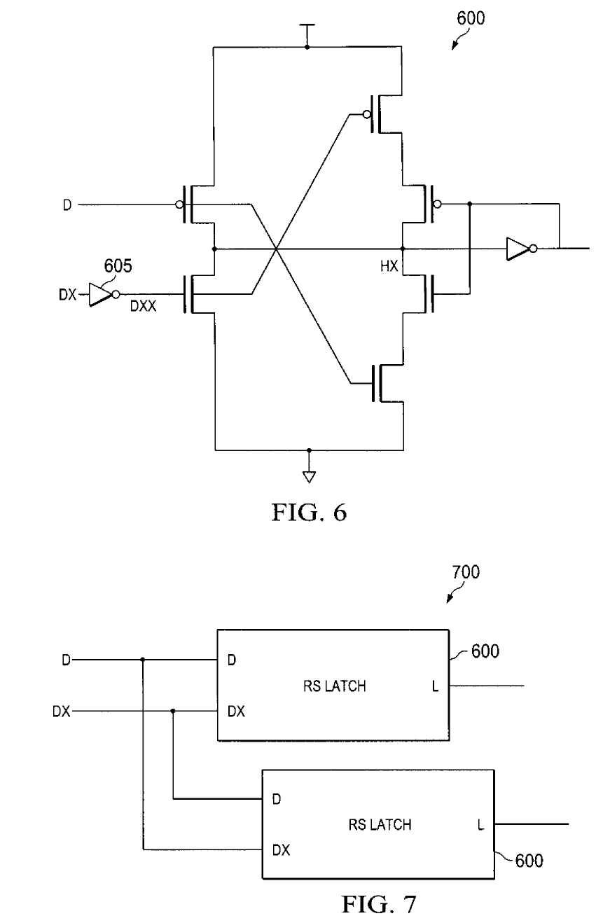

FIG. 6 shows an RS latch 600 according to an embodiment of the invention. In comparison to RS latch 300 according to an embodiment of the invention shown in FIG. 3A which is responsive to positive logic inputs, RS latch 600 is responsive to negative logic inputs by putting the input inverter 605 on the opposite data input as compared to RS latch 300 shown in FIG. 3A. Inverter 605 can be skewed to improve performance. In this case, the PMOS transistor would be increased in size and the NMOS transistor decreased in size, opposite to the skewing of the inverter 305 shown in FIG. 3A as described above.

FIG. 7 shows an RS latch arrangement 700 according to an embodiment of the invention which is a complementary output version of the RS latch 600 shown in FIG. 6. RS latch 700 comprises two RS latches 600 connected with swapped inputs D and DX. This circuit arrangement may be used when complementary output signals with minimum latency are both desired. Alternatively, an additional output inverter could be added to the L output of RS latch 600 to provide as complementary output at the cost of the delay of that additional inversion. However, RS latch 700 as shown in FIG. 7 avoids such a delay.

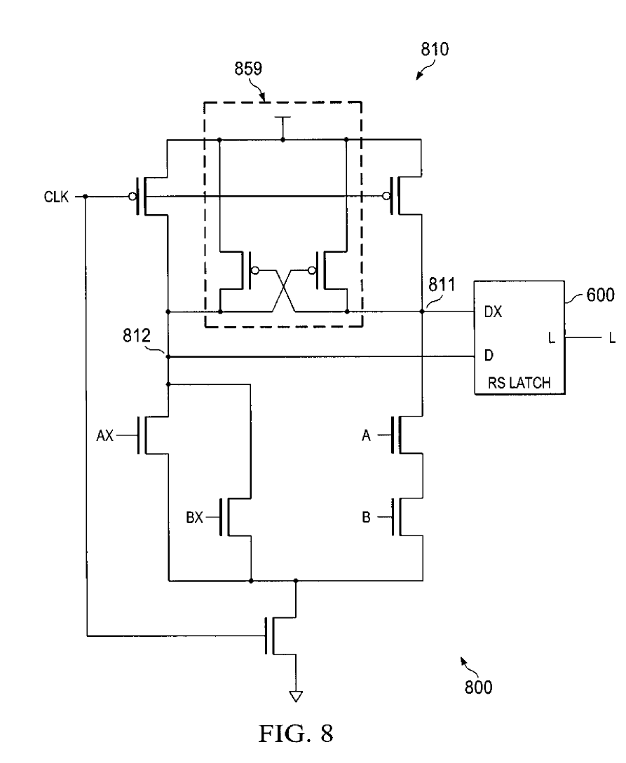

One exemplary application for the low active RS latch 600 shown in FIG. 6 is to create a dynamic gate, such as a domino gate with a latched output 800, such as the exemplary domino gate 810 shown in FIG. 8. Domino gate 810 performs the logical AND of inputs A and B, and is triggered off the rising edge of the clock input CLK. Domino gate includes first dynamic node 811 and second dynamic node 812. Domino gate 810 is shown including dual rail keeper circuit 859 embodied as cross coupled PFETs connected between the first and second dynamic nodes 811 and 812. Dual rail keeper circuit 859 makes domino gate 810 effectively static.

The low active inputs D and DX of the RS latch 600 can be connected to the domino gate dynamic nodes 812 and 811, respectively. The complementary output RS latch arrangement 700 of FIG. 7 could also be used if fast complementary outputs were desired. This arrangement is useful because it provides an improved delay in comparison to using the conventional NAND latch 500 shown in FIG. 5A. If a dynamic gate were used with dynamic nodes which would be precharged low and discharged to the positive supply through PMOS transistors, the high active RS latch 300 shown in FIG. 3 would generally be used instead.

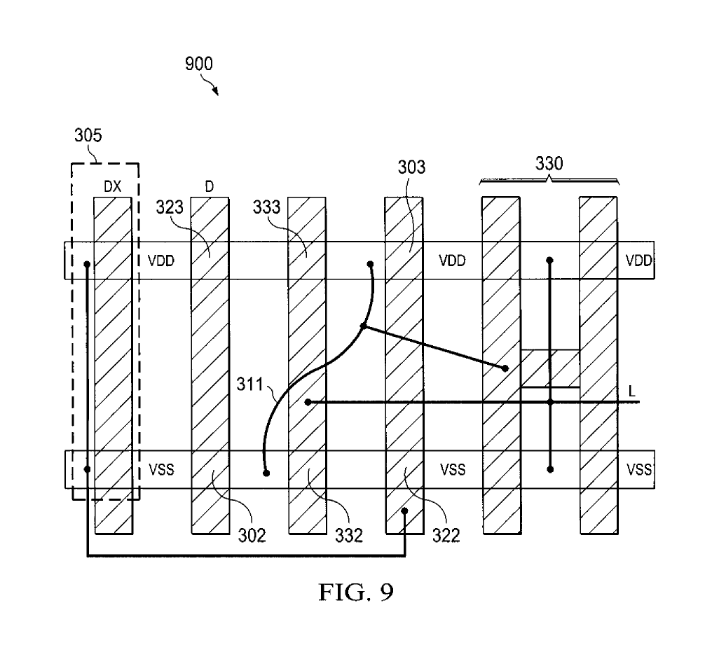

The RS latch 300 according to an embodiment of the invention shown in FIG. 3 can be laid out in an advantageous layout arrangement as demonstrated in the exemplary standard cell-based layout 900 shown in FIG. 9. Several of the devices in RS latch 300 as well as the latch node 311 are identified. Polysilicon lines are shown shaded, and generally include a silicide layer thereon. As can be seen, the N and P transistors with gates connected in common (e.g. 332, 333) to each node can be conveniently arranged in columns resulting in the straight poly gate geometries shown. While in this example all N and all P transistors are shown having the same size, it is possible to alter their sizes by jogging the inside edges of the N and P diffusions, for example to increase the size of the first two N devices on the left, and decrease the size of the next two N devices, while leaving room to increase the size of the fourth P device from the left of FIG. 9. This increases the W/L ratio of devices which increases the speed of transitions, while decreasing the sizes of feedback devices. It is also possible to alter the layout by increasing the number of transistor fingers of speed-critical devices, such as the first stage pull up device shown as 303 in FIGS. 3 and 9.

For example, pull up device 301 may be implemented with three transistor fingers instead of one. Moreover, wile the layout is shown with an output inverter with two poly gate fingers, output inverters with an increased or decreased number of gate fingers are also possible. The layout shown is made convenient by the stacking of the feedback/hold transistors shown in FIG. 3 (333 and 332) with the devices 332 and 322 with gates driven from the output node L connected to the latch node 311. It is also possible to reverse the order of devices 322 and 332, and of devices 323 and 333 generally without negative consequences on the delay characteristics, although a different layout arrangement would result.

As known in the art, the most fundamental latch is the RS latch generally described herein. As also known in the art, slight modifications to RS latches can be used to realize other latches. For example, a generally useful variation on the RS latch circuit is the Data latch, or D latch as it is generally called. As known in the art, the D latch can be constructed from an RS latch by using the inverted S input as the R input signal, thus the only difference that there is only one input, instead of two (R and S). Moreover, a JK latch can be formed from an RS latch by providing output feedback to the inputs, which is not present in the RS latch. When the two inputs of JK latch are shorted, a T Latch is formed. Accordingly, the present invention can be used to provide a variety of different latches.

It is appreciated by the Inventor transistor technology variations are contemplated in the context of the present invention. The invention is also not limited to the use of silicon wafers, nor CMOS designs.

Although the invention has been illustrated and described with respect to one or more implementations, equivalent alterations and modifications will occur to others skilled in the art upon the reading and understanding of this specification and the annexed drawings. In particular regard to the various functions performed by the above described components (assemblies, devices, circuits, systems, etc.), the terms (including a reference to a “means”) used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and/or the claims, such terms are intended to be inclusive in a manner similar to the term “comprising.”

The Abstract of the Disclosure is provided to comply with 37 C.F.R. § 1.72(b), requiring an abstract that will allow the reader to quickly ascertain the nature of the technical disclosure. It is submitted with the understanding that it will not be used to interpret or limit the scope or meaning of the following claims.

I claim:

1. An integrated circuit, comprising:
at least one latch circuit, said latch circuit comprising:
a first stage comprising a latch node positioned between a first pull up device operable to receive a first data signal and a first pull down device operative to receive second data signal;
a second stage comprising a second pull up device and a second pull down device having said latch node therebetween, wherein at least one gate of said first pull up or first pull down device is directly coupled to a gate of said second pull up or said second pull down device, and an output inverter coupled to said latch node.

2. The integrated circuit of claim 1, wherein an output of said output inverter provides an output for said latch circuit.

3. The integrated circuit of claim 2, further comprising hold circuitry coupled between said output of said latch circuit and said latch node operative to hold said output of said latch circuit.

4. The integrated circuit of claim 3, wherein said hold circuitry comprises an inverter including a first and a second transistor having their gates directly coupled, said gates of said first and a second transistor coupled to said output of said latch circuit.

5. The integrated circuit of claim 4, wherein said first and a second transistor both include a terminal directly coupled to said latch node, said first and a second transistor being positioned in a layout for said circuit at a top of a feedback stack.

6. The integrated circuit of claim 1, wherein said first pull up device comprises a first PMOS device operative to receive said first data signal and first pull device comprise a first NMOS transistor operative to receive said second data signal and said second pull up device comprises a second PMOS transistor and said second pull down device comprises a second NMOS transistor, wherein a gate of said first PMOS transistor is directly coupled to a gate of said second NMOS transistor and a gate of said first NMOS transistor is directly coupled to a gate of said second PMOS transistor.

7. The integrated circuit of claim 6, wherein said gate of said first PMOS transistor is directly coupled to said gate of said second NMOS transistor by a first polysilicon comprising line and said gate of said first NMOS transistor is directly coupled to said gate of said second PMOS transistor by a second polysilicon comprising line.

8. The integrated circuit of claim 6, further comprising an input inverter in series with a gate of one of said first pull up or pull down devices.

9. The integrated circuit of claim 8, wherein said input inverter is in series with a gate of said first PMOS transistor operable to provide said complement of said second data signal.

10. The integrated circuit of claim 9, wherein an NMOS transistor of said input inverter is sized larger than a PMOS transistor of said input inverter.

11. The integrated circuit of claim 9, wherein said at least one latch circuit comprises a first and a second of said latch circuit, said first and second latch circuits having said first and said second data signals swapped relative to said first NMOS transistor and said first PMOS transistor.

12. The integrated circuit of claim 9, further comprising at least one dynamic logic gate having first and second dynamic nodes, wherein said first dynamic node is coupled to a gate of said first NMOS transistor and said second dynamic node is coupled to a gate of said first PMOS.

13. The integrated circuit of claim 6, further comprising an input inverter in series with a gate of said first NMOS transistor operable to provide said complement of said first data signal.

14. The integrated circuit of claim 13, wherein a PMOS of said input inverter is sized larger than a NMOS of said input inverter.

15. The integrated circuit of claim 13, further comprising at least one dynamic logic gate having first and second dynamic nodes, wherein said first dynamic node is coupled to a gate of said first NMOS input transistor and said second dynamic node is coupled to a gate of said first PMOS transistor.

16. The integrated circuit of claim 6, wherein (i) said first PMOS transistor and said second NMOS transistor and (ii) said first NMOS transistor and said second PMOS transistor are arranged in columns and have a straight polysilicon comprising gate geometry.

17. The integrated circuit of claim 6, further comprising hold circuitry coupled between an output of said latch circuit and said latch node operative to hold said output of said latch circuit, wherein a layout of said integrated circuit comprises stacking transistors comprising said hold circuitry with said first and second NMOS transistors with gates driven from said output node of said latch circuit connected to said latch node.

18. An integrated circuit comprising at least one RS latch circuit, said RS latch circuit comprising:
a first stage comprising a latch node positioned between a first PMOS pull up device operative to receive said first data signal and a first NMOS pull down device operative to receive a second data signal;
a second stage comprising a second PMOS pull up device and a second NMOS pull down device, wherein a gate of said first PMOS device is directly coupled to a gate of said second NMOS device and a gate of said first NMOS device is directly coupled to a gate of said second PMOS device,
an output inverter coupled to said latch node, and
hold circuitry comprising a first and a second hold transistor having their gates directly coupled, said gates of said first and a second hold transistor coupled to an output of said clocked latch circuit operative to hold said output of said latch circuit.

19. The integrated circuit of claim 18, wherein said at least one latch circuit comprises a first and a second of said latch circuit, said first and second latch circuits having said first and said second data signals swapped relative to said first NMOS pull down device and said first PMOS pull up device.

20. The integrated circuit of claim 18, further comprising an input inverter in series with a gate of said first NMOS pull down device operable to provide said complement of said first data signal.
